(19) United States
(12) Patent Application Publication
(10) Pub. No.: US 2019/0279960 A1
(43) Pub. Date: Sep. 12, 2019

(54) INTEGRATED CIRCUIT PACKAGES WITH PLATES

(71) Applicant: Intel Corporation, Santa Clara, CA (US)

(72) Inventors: Omkar G. Karhade, Chandler, AZ (US); Edvin Cetegen, Chandler, AZ (US); Sandeep B. Sane, Chandler, AZ (US)

(73) Assignee: Intel Corporation, Santa Clara, CA (US)

(21) Appl. No.: 16/349,959

(22) PCT Filed: Dec. 14, 2016
(86) PCT No.: PCT/US2016/066433

§ 371 Date: May 14, 2019

(51) Int. Cl. H01L 25/065; H01L 23/00; H01L 23/522; H01L 21/56; H05K 1/18

(52) U.S. Cl. CPC H01L 25/0652; H01L 24/09; H01L 24/17; H01L 2924/1432; H01L 21/563; H05K 1/181; H01L 2224/0401; H01L 23/5226

(57) ABSTRACT

Disclosed herein are integrated circuit (IC) packages with plates, as well as related devices and methods. For example, in some embodiments, an IC package may include: a package substrate; a plurality of electrical components secured to a face of the package substrate; and a plate secured to the plurality of electrical components with an adhesive such that the plurality of electrical components are between the plate and the package substrate.

### BACKGROUND

Small integrated circuit (IC) packages are conventionally fabricated by encasing the components on the of the package substrate in a mold material. Second level interconnects (SLI) on the front side may be used to attach the IC package to another component (e.g., a circuit board).

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIGS. 1A-1B are various views of integrated circuit (IC) device including an IC package with a plate, in accordance with some embodiments.

FIG. 2 is a cross-sectional side view of an IC device including an IC package with another example of a plate, in accordance with some embodiments.

FIGS. 3A-3D are cross-sectional side views of various stages in the manufacture of the IC device of FIG. 1, in accordance with various embodiments.

FIG. 4 is a flow diagram of an example method of manufacturing an IC package including a plate, in accordance with various embodiments.

FIGS. 5A-5B are top views of a wafer and dies that may be used in any of the IC packages disclosed herein.

FIG. 6 is a cross-sectional side view of an IC device that may be included in a die of an IC package having any of the package substrates disclosed herein.

FIG. 7 is a cross-sectional side view of an IC device assembly that may include any of the embodiments of the package substrates disclosed herein.

FIG. 8 is a block diagram of an example computing device that may include any of the embodiments of the package substrates disclosed herein.

### DETAILED DESCRIPTION

Disclosed herein are integrated circuit (IC) packages with plates, as well as related devices and methods. For example, in some embodiments, an IC package may include: a package substrate; a plurality of electrical components secured to a face of the package substrate; and a plate secured to the plurality of electrical components with an adhesive such that the plurality of electrical components are between the plate and the package substrate.

Some conventional IC packages (especially those used in “ultrasmall” applications) may cover the electrical components on one side of the package substrate with an overmold material in order to mechanically secure the components to the package substrate and provide a flat “back side” surface for marking. Some such IC packages may suffer from reliability issues. For example, the solder that electrically couples the electrical components to the package substrate may have a different coefficient of thermal expansion (CTE) than the proximate solder resist on the package substrate and than the proximate layers of the package substrate. During operation of the electrical components, the heat generated by the electrical components may cause differential expansion of the solder and the proximate solder resist/layers; the combination of this differential expansion and the mechanical constraint provided by the overmold material may cause breakage at the interface between the electrical components and the package substrate. Additionally, some of the materials may outgas as they are heated; because the overmold material may prevent some of the gas from escaping, pressure may build at the interface between the electrical components and the package substrate, and this pressure may result in breakage. Additionally, when the overmold material is also used to underfill the electrical components, this underfill is often incomplete, leaving voids in the overmold material between different portions of solder (e.g., different solder bumps or balls). During reflow of the solder, the presence of such a void may cause the solder to be extruded into the void, resulting in solder bridging and an electrical short. These reliability issues may be particularly costly in a process flow in which the electrical components are first coupled to the package substrate, then overmolded; if breakage occurs in the final package due to the overmolding, the entire package must likely be discarded. The more costly the electrical components (e.g., when the overmolded electrical components include a complex processing device, or when such a device is coupled to the other side of the package substrate), the more detrimental the loss of the whole package.

Various ones of the IC packages disclosed herein may avoid overmolding while still providing an IC package that is mechanically robust, markable, and handleable during test. These IC packages may exhibit improved reliability relative to previous packages, and may enable the effective scaling down of the size of these packages to regimes not practically achievable using conventional technology.

In the following detailed description, reference is made to the accompanying drawings that form a part hereof, wherein like numerals designate like parts throughout, and in which is shown, by way of illustration, embodiments that may be practiced. It is to be understood that other embodiments may be utilized and structural or logical changes may be made without departing from the scope of the present disclosure. Therefore, the following detailed description is not to be taken in a limiting sense.

Various operations may be described as multiple discrete actions or operations in turn, in a manner that is most helpful in understanding the disclosed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges. As used herein, a “high-k dielectric material” may refer to a material having a higher dielectric constant than silicon oxide.

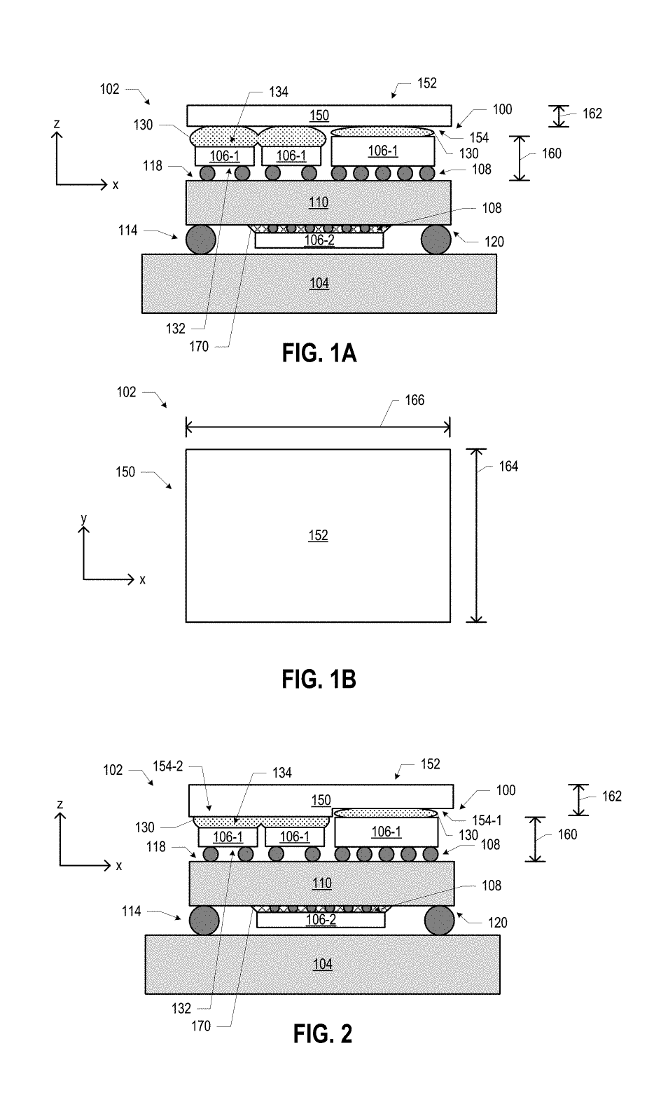

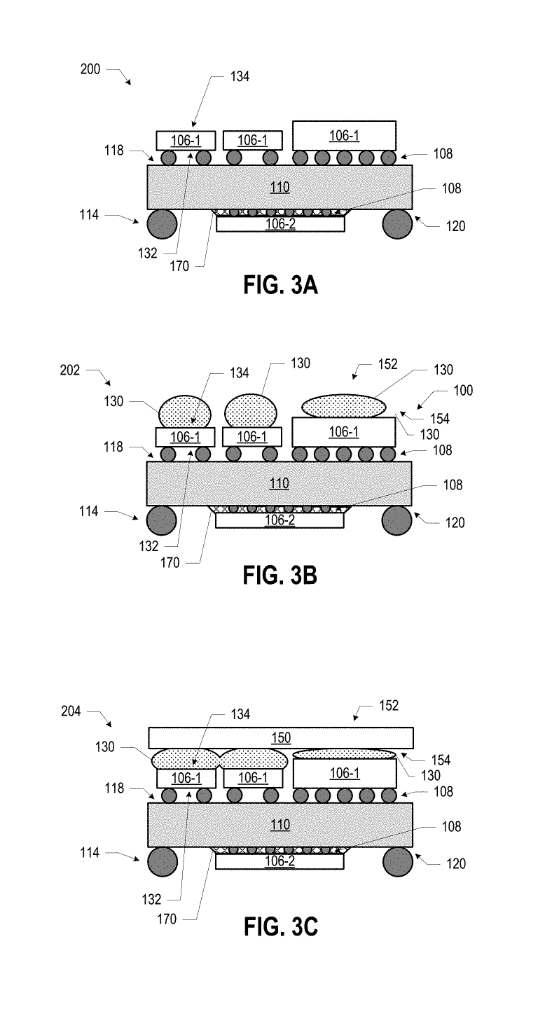

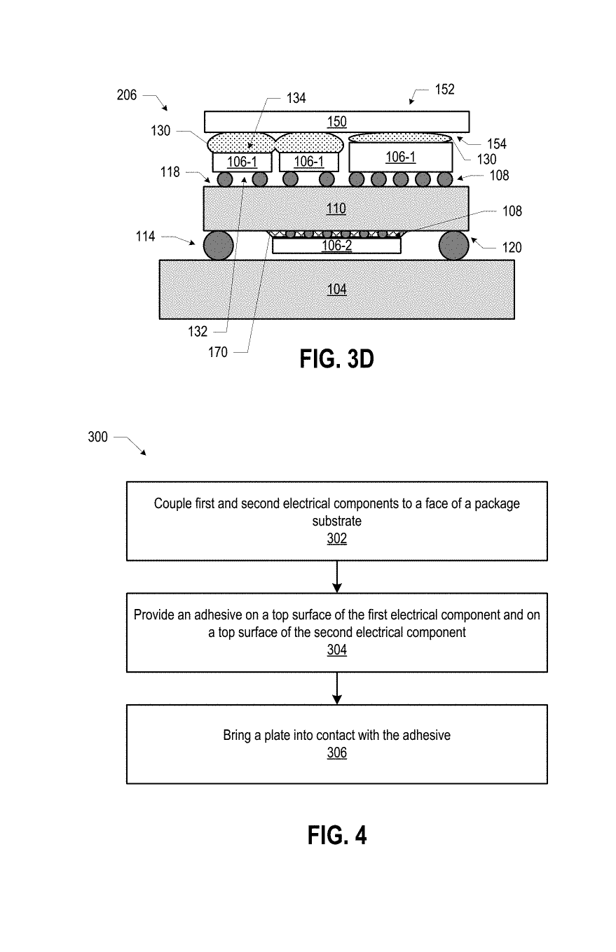

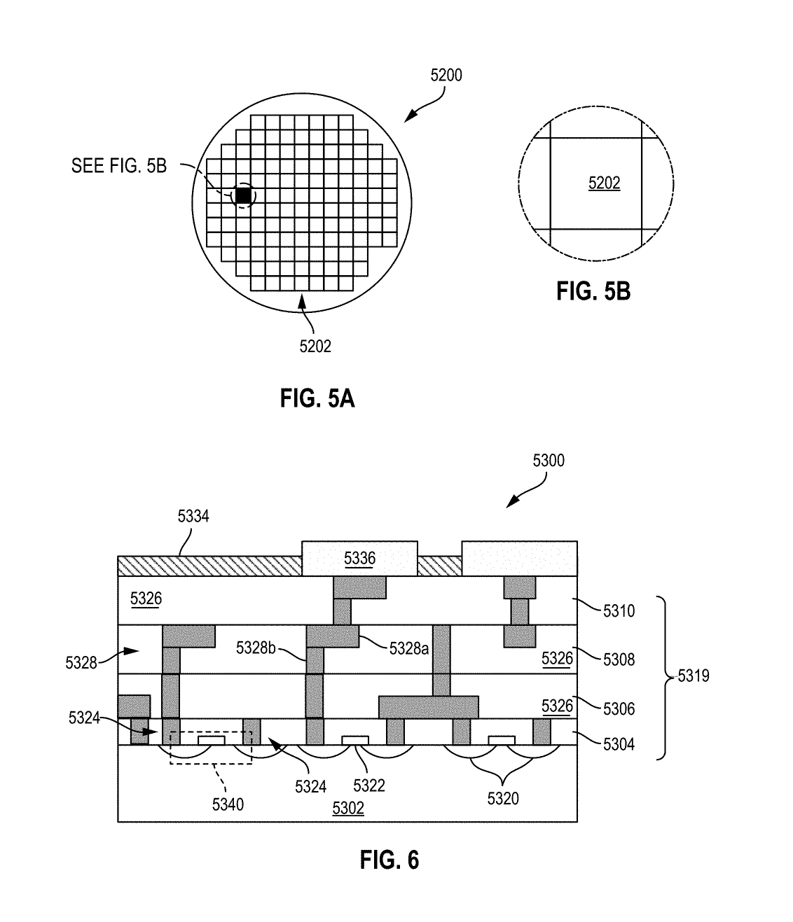

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. For ease of discussion, the term “FIG. 1” may be used to refer to the collection of drawings of FIGS. 1A-1B, the term “FIG. 3” may be used to refer to the collection of drawings of FIGS. 3A-3D, and the term “FIG. 5” may be used to refer to the collection of drawings of FIGS. 5A-5B.

FIGS. 1A-1B are various views of an integrated circuit (IC) device 102 including an IC package 100 with a plate 150, in accordance with some embodiments. In particular, FIG. 1A is a side cross-sectional view of an IC device 102 with a particular embodiment of a plate 150, and FIG. 1B is a top view of the IC device 102 of FIG. 1A.

The IC package 100 may include a package substrate 110 and multiple electrical components 106 disposed thereon. In particular, multiple electrical components 106-1 may be coupled to a first face 118 of the package substrate 110 via first level interconnects 108, as illustrated. In some embodiments, one or more electrical components 106-2 may also be coupled to a second face 120 of the package substrate 110 via first level interconnects 108, as illustrated. In some embodiments, the first level interconnects 108 may include solder bumps or balls (as illustrated in FIG. 1); in other embodiments, the first level interconnects 108 may include wirebonds or any other suitable interconnect. In particular, the package substrate 110 may include bond pads or other conductive contacts to couple to the first level interconnects 108; in some embodiments, the conductive contacts may be surrounded by solder resist, as known in the art.

Although three electrical components 106-1 and one electrical component 106-2 are illustrated in FIG. 1, this is simply an example, and the IC package 100 may include fewer or more electrical components 106-1 and/or 106-2 (which may, for example, have any number of different footprints and heights). The electrical components 106 may have any suitable functionality, and may include passive devices (e.g., resistors, capacitors, and/or inductors), active devices (e.g., processing devices, memory, communications devices, and/or sensors), or any other computing components or circuitry. For example, in some embodiments, the electrical components 106-1 may include active and/or passive components (e.g., capacitors, memory devices, radiofrequency (RF) components), and the electrical components 106-2 may include a processing device (e.g., a central processing unit (CPU). In some embodiments, the electrical components 106 may be dies (e.g., as discussed below with reference to FIG. 5).

The electrical components 106 may have any suitable dimensions. For example, in some embodiments, the maximum height 160 (e.g., z-height) of the electrical components 106-1 (measured from the first face 118) may be between 100 microns and 1.5 millimeters (e.g., between 200 microns and 1 millimeter). The first face 154 of the plate 150 may be spaced apart from the first face 118 of the package substrate 110 by a distance equal to the maximum height 160 plus the thickness of the adhesive 130 on the electrical component 106-1 having the height 160. In some embodiments, the thickness of the adhesive 130 on an electrical component 106-1 may be between 10 microns and 1.5 millimeters (e.g., between 20 microns and 1 millimeter).

As illustrated in FIG. 1, each of the electrical components 106-1 may have a first face 132 and an opposing second face 134 (the reference numerals 132 and 134 are only applied to a single electrical component 106-1 in FIG. 1 for ease of illustration). The first level interconnects 118 may be disposed between the first face 132 of the electrical component 106-1 and the first face 108 of the package substrate 110. An adhesive material 130 may be disposed on the second faces 134 of the electrical components 106-1, and the first face 154 of the plate 150 may be disposed on the adhesive material 130. In FIG. 1, all of the depicted electrical components 106-1 have adhesive material 130 disposed on their second faces 134, but this need not be the case; in some embodiments, some of the electrical components 106-1 on the first face 118 of the package substrate 110 may not have adhesive material 130 disposed on their second faces 134. Thus, in some embodiments, an IC package 100 may include some electrical components 106-1 that do have adhesive material 130 disposed on their second faces 134, and some electrical components 106-1 that do not.

The plate 150 may take any of a number of forms. In some embodiments, the plate 150 may have a thickness 162 that may be between 20 microns and 150 microns (e.g., between 20 microns and 100 microns, between 30 microns and 100 microns, between 20 microns and 30 microns, or between 30 microns and 50 microns). In some embodiments, the thickness 162 of the plate 150 may be substantially less than the thickness of a conventional heat spreader, which typically has a thickness greater than 1 millimeter in order to adequately sink and spread heat. As represented in FIG. 1B, the heat spreader 150 may have a width 164 and a length 166; the width 164 and the length 166 may be the same, or they may be different. In some embodiments, the width 164 and the length 166 may each be between 0.75 centimeters and 1.5 centimeters. In some embodiments, the area of the footprint of the heat spreader 150 (i.e., the product of the width 164 and the length 166) may be between 0.75 square centimeters and 2 square centimeters (e.g., between 0.75 square centimeters and 1.5 square centimeters, or between 0.75 square centimeters and 1.25 square centimeters). For example, in some embodiments, the width 164 and the length 166 may each be approximately 1 centimeter.

Any suitable material or materials may be used to form the plate 150. For example, in some embodiments, the plate 150 may include a metal, such as copper, aluminum, or steel. In some embodiments, the plate 150 may include a polymer material. In some embodiments, the plate 150 may include a plastic material. Such a plastic material may have a melting temperature greater than the melting temperature of solder included in the first level interconnects 108 and greater than the melting temperature of solder included in the second level interconnects 114 (e.g., approximately 260 degrees Celsius for some solders) in order to avoid melting or warpage of the plate 150 during solder reflow. In some embodiments, the plate 150 may include a ceramic material.

The material or materials chosen for the plate 150 may be selected to achieve various material properties. For example, in some embodiments, the plate 150 may have a thermal conductivity lower than the thermal conductivity of copper (e.g., lower than 385 Watts per meter Kelvin). In some embodiments, the plate 150 may have a thermal conductivity lower than the thermal conductivity of aluminum (e.g., lower than 205 Watts per meter Kelvin). Because the plate 150 need not function as a heat spreader or heat sink, the thermal conductivity of the plate 150 may be lower than would be acceptable in a heat spreader or heat sink.

Any suitable material may be used for the adhesive 130. For example, the adhesive 130 may be an underfill material conventionally used between flip chip dies and the substrate on which they are mounted. In some embodiments, the adhesive 130 may have a viscosity (before curing) between 10 Pascal seconds and 60 Pascal seconds; higher viscosities may make manufacturing easier because the adhesive 130 may not excessively spread before curing. In some embodiments, the adhesive 130 may have a modulus of elasticity between 6 gigapascals and 13 gigapascals. In some embodiments, the adhesive 130 may have a coefficient of thermal expansion between 20 parts per million per degree Celsius and 45 parts per million per degree Celsius. In some embodiments, the adhesive 130 may be a fast-curing material.

As discussed below with reference to FIG. 3B, different ones of the electrical components 106-1 may have different volumes of adhesive 130 disposed thereon. For example, “taller” electrical components 106-1 may have less adhesive 130 disposed on their faces 134 than “shorter” electrical components 106-1; the difference in volume of the adhesive 130 may compensate for the different distances between the plate 150 and the faces 134. In some embodiments, the adhesive 130 disposed on 2 or more adjacent electrical components 106-1 may be in contact (e.g., as illustrated in FIG. 1A for the 2 leftmost electrical components 106-1). The amount of the adhesive 130 provided on the electrical components 106-1 may, in some embodiments, be selected to be small enough so that the adhesive 130 does not contact the first face 118 of the package substrate 110. In some embodiments, the adhesive 130 may not contact the first level interconnects 108 between the electrical components 106-1 and the package substrate 110. In some embodiments, the adhesive 130 may not contact the side faces of the electrical components 106-1.

In some embodiments, no underfill material may be disposed around the first level interconnects 108 at the first face 118 of the package substrate 110. In some embodiments, no underfill material may be disposed between the electrical components 106-1 and the first face 118 of the package substrate 110. In some embodiments in which one or more electrical components 106-2 are disposed at the second face 120 of the package substrate 110, an underfill material 170 may be disposed between the second face 120 and the electrical component 106-2; in other embodiments, no underfill material may be present at the second face 120.

In some embodiments, no mold compound may be present between the plate 150 and the package substrate 110. In some embodiments, no mold compound may contact the first face 118 of the package substrate 110. In some embodiments, different ones of the electrical components 106-1 may be spaced apart by an open volume (rather than, e.g., being physically bridged by a mold compound). Similarly, in some embodiments, at least some portions of the first faces 132 of the electrical components 106-1 may be spaced apart from the first face 118 by open volumes (rather than, e.g., being physically bridged by a mold compound “underfilling” the electrical component 106-1). In some embodiments, no mold compound may be present “above” or at the sides of the plate 150.

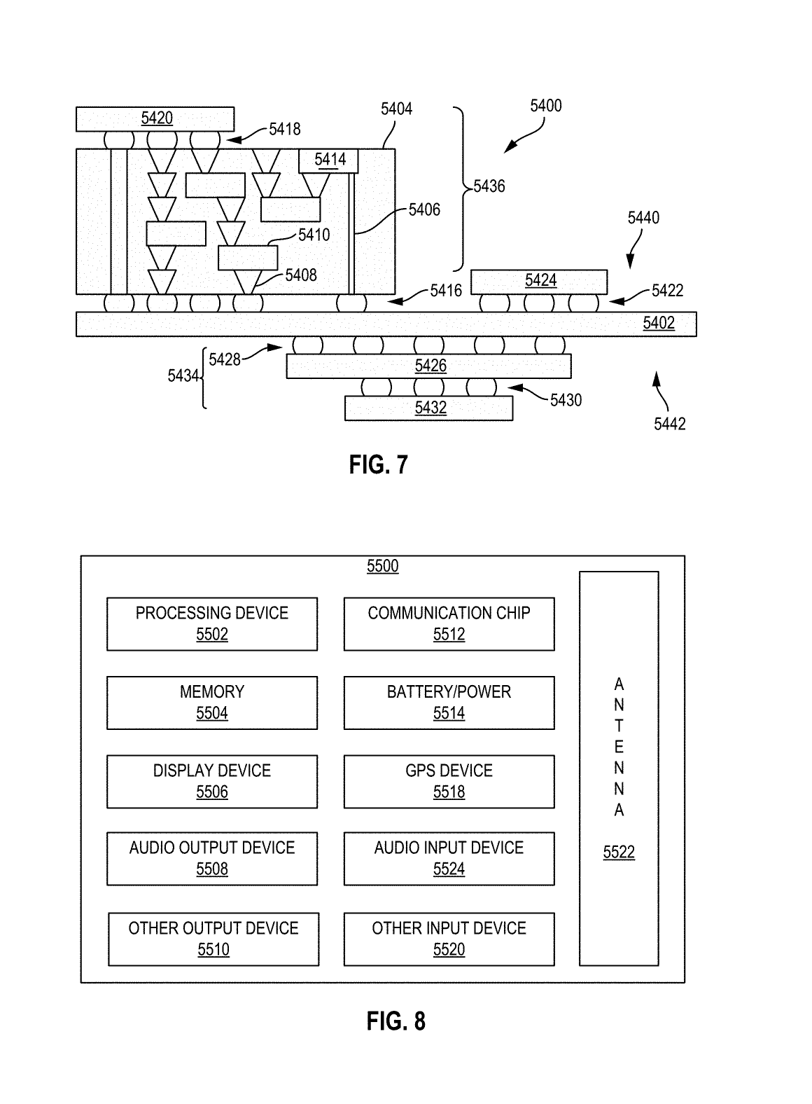

The package substrate 110 may be coupled to a circuit board 104 via the second level interconnects 114 disposed at the second face 120 of the package substrate 110. In some embodiments, the second level interconnects 114 may include solder balls (as illustrated in FIG. 1) for a ball grid array (BGA) coupling; in other embodiments, the second level interconnects 114 may include solder paste contacts to provide land grid array (LGA) interconnects, or any other suitable interconnect. The circuit board 104 may include conductive pathways (not shown) that allow power, ground, and other electrical signals to move between the circuit board 104 and the IC package 100, as known in the art. Although FIG. 1 illustrates a single IC package 100 disposed on the circuit board 104, this is simply for ease of illustration and multiple IC packages may be disposed on the circuit board 104 (e.g., as discussed below with reference to the circuit board 5402 of the assembly 5400 of FIG. 7). In some embodiments, the circuit board 104 may be a printed circuit board (PCB) (e.g., a motherboard). In some embodiments, the circuit board 104 may be another IC package, and the IC device 102 may be a package-on-package structure. In some embodiments, the circuit board 104 may be an interposer, and the IC device 102 may be a package-on-interposer structure.

The package substrate 110 may include an insulating material and one or more conductive pathways through the insulating material, in accordance with various embodiments. In some embodiments, the insulating material may be provided by a single material, while in other embodiments, the insulating material may include different layers formed of different materials. For example, a “base” layer of insulating material may be provided by a glass fiber reinforced core, a rigid carrier, or a peelable core panel, for example, while additional layers of insulating material may be provided by an epoxy-based laminate. In some embodiments, the package substrate 110 may be an organic substrate. For example, in some embodiments, the insulating material of the package substrate 110 may be an organic material, such as an epoxy-based laminate. The insulating material may be, for example, a build-up film (e.g., Ajinomoto build-up film). The insulating material may include, for example, an epoxy with a phenolic hardener. The conductive pathways in the package substrate 110 may couple any of the electrical components 106 to the circuit board 104 (e.g., via the first level interconnects 108 and the second level interconnects 114), and/or may couple multiple ones of the electrical components 106 to each other (e.g., via the first level interconnects 108). Any suitable arrangement of conductive pathways 116 may couple the electrical components 106 and the circuit board 104, as desired.

The plate 150 may have a second face 152 opposite to the first face 154. In some embodiments, the second face 152 may be flat. A flat second face 152 may enable marking (e.g., laser marking) during manufacture and may also facilitate testing by allowing the IC package 100 to rest stably on the plate 150 in a test fixture. In some embodiments, the first face 154 may also be flat. In other embodiments, the first face 154 may not be flat. For example, FIG. 2 is a cross-sectional side view of an embodiment of the IC device 102 in which the plate 150 has a first face 154 that is not flat. Instead, the plate 150 of FIG. 2 has 2 different portions 154-1 and 154-2, with the portion 154-1 recessed with reference to the portion 154-2. The recessed portion 154-1 may accommodate the greater height of the rightmost electrical component 106-1 relative to the lesser heights of the 2 leftmost electrical components 106-1 illustrated in FIG. 2, and thus may allow less adhesive 130 to be used relative to the embodiment illustrated in FIG. 1. Although the plate 150 as illustrated in FIG. 2 is having only 2 regions with different thicknesses, this is simply for ease of illustration, and the plate 150 may have any desired thicknesses or any desired pattern of features (e.g., recesses) at the first face 154. For example, the first face 154 may have 2 or more different recessed portions to accommodate 2 or more different electrical components 106-1. Other than the contours of the first face 154 of the plate 150, the IC device 102 of FIG. 2 may take any of the forms discussed herein with reference to FIG. 1. For example, the thickness 162 of the plate 150 of FIG. 2 (representing the maximum thickness of the plate 150) may take any of the forms discussed above with reference to the thickness 162 of the plate 150 of FIG. 1.

Any suitable techniques may be used to manufacture the IC packages 100 and the IC devices 102 disclosed herein. For example, FIGS. 3A-3D are cross-sectional side views of various stages in the manufacture of the IC device 102 of FIG. 1, in accordance with various embodiments. The operations discussed below with reference to FIGS. 3A-3C may be performed to manufacture the IC package 100. Although FIGS. 3A-3D illustrate the manufacture of the particular IC device 102 illustrated in FIG. 1, the techniques discussed below with reference to FIGS. 3A-3D may be used to manufacture any suitable ones of the IC packages 100 and IC devices 102 disclosed herein.

FIG. 3A is a cross-sectional side view of an assembly 200 including multiple electrical components 106 coupled to a package substrate 110. In particular, electrical components 106-1 may have first faces 132 coupled to a first face 118 of the package substrate 110 by first level interconnects 108. The electrical components 106 may have second faces 134 and electrical component 106-2 may be coupled to a second face 120 of the package substrate 110 by first level interconnects 108. Second level interconnects 114 may also be disposed at the second face 120.

FIG. 3B is a cross-sectional side view of an assembly 202 subsequent to providing an adhesive 130 on the second faces 134 of the electrical components 106-1 of the assembly 200 (FIG. 3A). Different portions of the adhesive 130 may be provided on the second faces 134 of multiple ones of the electrical components 106-1 (e.g., by an automated dispensing system). As discussed above, in some embodiments, portions of the adhesive 130 may be disposed on the second faces 134 of all of the electrical components 106-1, while in other embodiments, portions of the adhesive 130 may be disposed on the second faces 134 of some, but not all, of the electrical components 106-1. The volume of the adhesive 130 provided on different ones of the electrical components 106-1 may differ. For example, as discussed above, more adhesive 130 may be disposed on “shorter” ones of the electrical components 106-1 than “taller” ones of the electrical components 106-1. The adhesive 130 of the assembly 202 may take the form of any of the adhesives 130 discussed herein.

FIG. 3C is a cross-sectional side view of an assembly 204 subsequent to bringing a plate 150 in contact with the adhesive 130 of the assembly 202 (FIG. 3B) and curing the adhesive 130 to secure the plate 150 to the remainder of the assembly 204. The plate 150 may be positioned so that it is located at a desired height above the first face 118 of the package substrate 110, and may be held in place during the curing of the adhesive 130. The curing conditions for the adhesive 130 may depend on the properties of the adhesive 130, and may include waiting for a predetermined curing time, exposing the adhesive 130 to heat, exposing the adhesive 130 to ultraviolet or other radiation, or any other curing condition associated with the adhesive 130. In some embodiments, the volume of adhesive 130 provided in the assembly 202 may be selected so that the adhesive 130 does not contact the package substrate 110 after the plate 150 has been brought into contact with the adhesive 130. The assembly 204 may take the form of the IC package 100 of FIG. 1, but the plate 150 of the assembly 204 may take the form of any of the plates 150 disclosed herein (e.g., a plate 150 having a first face 154 that is not flat, as discussed above with reference to FIG. 2). The plate 150 may be formed using any suitable technique, such as cutting the plate 150 out of a sheet of material, pressing features into a sheet of material, molding the plate 150 (e.g., by providing a fluid material in a mold in the desired shape and curing the fluid material), milling the plate 150 from a block of material, etc.

FIG. 3D is a cross-sectional side view of an assembly 206 subsequent to coupling the assembly 204 (FIG. 3C) to a circuit board 104. The assembly 204 may be secured to the circuit board 104 by the second level interconnects 114 (e.g., by a pick and place operation combined with solder reflow). The assembly 206 may take the form of the IC device 100 of FIG. 1.

FIG. 4 is a flow diagram of an example method 300 of manufacturing an IC package including a plate, in accordance with various embodiments. Although the various operations discussed with reference to the method 300 are shown in a particular order and once each, the operations may be performed in any suitable order (e.g., in any combination of parallel or series performance), and may be repeated or omitted as suitable. Additionally, although various operations of the method 300 may be illustrated with reference to particular embodiments of the IC package 100 disclosed herein, these are simply examples, and the method 300 may be used to form any suitable IC package.

At 302, first and second electrical components may be coupled to a face of a package substrate. For example, multiple electrical components 106-1 may be coupled to the first face 118 of the package substrate 110 by first level interconnects 108 (e.g., as discussed above with reference to FIG. 3A). In some embodiments, one or more additional electrical components may be coupled to the opposite face of the package substrate as part of 302; for example, one or more electrical components 106-2 may be coupled to the second face 120 of the package substrate 110 by first level interconnects 108.

At 304, an adhesive may be provided on a top surface of the first electrical component and on a top surface of the second electrical component. For example, different portions of an adhesive 130 may be provided on the second faces 134 of multiple ones of the electrical components 106-1 (e.g., as discussed above with reference to FIG. 3B).

At 306, a plate may be brought into contact with the adhesive. For example, a plate 150 may be brought into contact with the adhesive 130 (e.g., as discussed above with reference to FIG. 3C). In some embodiments, the plate may be positioned so that a top surface of the plate may be parallel with the face of the package substrate (e.g., the plate 150 may be positioned such that the second face 152 of the plate 150 is parallel with the first face 118 of the package substrate 110).

The IC packages 100 disclosed herein may include, or be included in, any suitable electronic device. FIGS. 5-10 illustrate various examples of apparatuses that may be included in, or that may include, one or more of any of the IC packages 100 disclosed herein.

FIGS. 5A-5B are top views of a wafer 5200 and dies 5202 that may be included in any of the IC packages 100 disclosed herein. The wafer 5200 may be composed of semiconductor material and may include one or more dies 5202 having IC elements formed on a surface of the wafer 5200. Each of the dies 5202 may be a repeating unit of a semiconductor product that includes any suitable IC. After the fabrication of the semiconductor product is complete, the wafer 5200 may undergo a singulation process in which each of the dies 5202 is separated from one another to provide discrete “chips” of the semiconductor product. The die 5202 may include one or more transistors (e.g., some of the transistors 5340 of FIG. 6, discussed below) and/or supporting circuitry to route electrical signals to the transistors, as well as any other IC components. In some embodiments, the wafer 5200 or the die 5202 may include a memory device (e.g., a static random access memory (SRAM) device), a logic device (e.g., AND, OR, NAND, or NOR gate), or any other suitable circuit element. Multiple ones of these devices may be combined on a single die 5202. For example, a memory array formed by multiple memory devices may be formed on a same die 5202 as a processing device (e.g., the processing device 5502 of FIG. 8) or other logic that is configured to store information in the memory devices or execute instructions stored in the memory array.

FIG. 6 is a cross-sectional side view of an IC device 5300 that may be included in an electrical component 106 that may be included in any of the IC packages 100 disclosed herein. The IC device 5300 may be formed on a substrate 5302 (e.g., the wafer 5200 of FIG. 5A) and may be included in a die (e.g., the die 5202 of FIG. 5B). The substrate 5302 may be a semiconductor substrate composed of semiconductor material systems including, for example, N-type or P-type materials systems. The substrate 5302 may include, for example, a crystalline substrate formed using a bulk silicon or a silicon-on-insulator substructure. In some embodiments, the substrate 5302 may be formed using alternative materials, which may or may not be combined with silicon, that include but are not limited to germanium, indium antimonide, lead telluride, indium arsenide, indium phosphide, gallium arsenide, or gallium antimonide. Further materials classified as group II-VI, III-V, or IV may also be used to form the substrate 5302. Although a few examples of materials from which the substrate 5302 may be formed are described here, any material that may serve as a foundation for an IC device 5300 may be used. The substrate 5302 may be part of a singulated die (e.g., the dies 5202 of FIG. 5B) or a wafer (e.g., the wafer 5200 of FIG. 5A).

The IC device 5300 may include one or more device layers 5304 disposed on the substrate 5302. The device layer 5304 may include features of one or more transistors 5340 (e.g., metal oxide semiconductor field-effect transistors (MOSFETs)) formed on the substrate 5302. The device layer 5304 may include, for example, one or more source and/or drain (S/D) regions 5320, a gate 5322 to control current flow in the transistors 5340 between the S/D regions 5320, and one or more S/D contacts 5324 to route electrical signals to/from the S/D regions 5320. The transistors 5340 may include additional features not depicted for the sake of clarity, such as device isolation regions, gate contacts, and the like. The transistors 5340 are not limited to the type and configuration depicted in FIG. 6 and may include a wide variety of other types and configurations such as, for example, planar transistors, nonplanar transistors, or a combination of both. Nonplanar transistors may include FinFET transistors, such as double-gate transistors or tri-gate transistors, and wraparound or all-around gate transistors, such as nanoribbon and nanowire transistors.

Each transistor 5340 may include a gate 5322 formed of at least two layers, a gate dielectric layer and a gate electrode layer. The gate dielectric layer may include one layer or a stack of layers. The one or more layers may include silicon oxide, silicon dioxide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer to improve its quality when a high-k material is used.

The gate electrode layer may be formed on the gate dielectric layer and may include at least one P-type work-function metal or N-type work-function metal, depending on whether the transistor 5340 is to be a PMOS or an NMOS transistor. In some implementations, the gate electrode layer may consist of a stack of two or more metal layers, where one or more metal layers are work-function metal layers and at least one metal layer is a fill metal layer. Further metal layers may be included for other purposes, such as a barrier layer. For a PMOS transistor, metals that may be used for the gate electrode include, but are not limited to, ruthenium, palladium, platinum, cobalt, nickel, and conductive metal oxides (e.g., ruthenium oxide). For an NMOS transistor, metals that may be used for the gate electrode include, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide).

In some embodiments, when viewed as a cross section of the transistor 5340 along the source-channel-drain direction, the gate electrode may consist of a U-shaped structure that includes a bottom portion substantially parallel to the surface of the substrate and two sidewall portions that are substantially perpendicular to the top surface of the substrate. In other embodiments, at least one of the metal layers that form the gate electrode may simply be a planar layer that is substantially parallel to the top surface of the substrate and does not include sidewall portions substantially perpendicular to the top surface of the substrate. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from a material such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 5320 may be formed within the substrate 5302 adjacent to the gate 5322 of each transistor 5340. The S/D regions 5320 may be formed using either an implantation/diffusion process or an etching/deposition process, for example. In the former process, dopants such as boron, aluminum, antimony, phosphorous, or arsenic may be ion-implanted into the substrate 5302 to form the S/D regions 5320. An annealing process that activates the dopants and causes them to diffuse farther into the substrate 5302 may follow the ion-implantation process. In the latter process, the substrate 5302 may first be etched to form recesses at the locations of the S/D regions 5320. An epitaxial deposition process may then be carried out to fill the recesses with material that is used to fabricate the S/D regions 5320. In some implementations, the S/D regions 5320 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 5320 may be formed using one or more alternate semiconductor materials such as germanium or a group III-V material or alloy. In further embodiments, one or more layers of metal and/or metal alloys may be used to form the S/D regions 5320.

Electrical signals, such as power and/or input/output (I/O) signals, may be routed to and/or from the transistors 5340 of the device layer 5304 through one or more interconnect layers disposed on the device layer 5304 (illustrated in FIG. 6 as interconnect layers 5306-5310). For example, electrically conductive features of the device layer 5304 (e.g., the gate 5322 and the S/D contacts 5324) may be electrically coupled with the interconnect structures 5328 of the interconnect layers 5306-5310. The one or more interconnect layers 5306-5310 may form an interlayer dielectric (ILD) stack 5319 of the IC device 5300.

The interconnect structures 5328 may be arranged within the interconnect layers 5306-5310 to route electrical signals according to a wide variety of designs (in particular, the arrangement is not limited to the particular configuration of interconnect structures 5328 depicted in FIG. 6). Although a particular number of interconnect layers 5306-5310 is depicted in FIG. 6, embodiments of the present disclosure include IC devices having more or fewer interconnect layers than depicted.

In some embodiments, the interconnect structures 5328 may include trench structures 5328a (sometimes referred to as “lines”) and/or via structures 5328b (sometimes referred to as “holes”) filled with an electrically conductive material such as a metal. The trench structures 5328a may be arranged to route electrical signals in a direction of a plane that is substantially parallel with a surface of the substrate 5302 upon which the device layer 5304 is formed. For example, the trench structures 5328a may route electrical signals in a direction in and out of the page from the perspective of FIG. 6. The via structures 5328b may be arranged to route electrical signals in a direction of a plane that is substantially perpendicular to the surface of the substrate 5302 upon which the device layer 5304 is formed. In some embodiments, the via structures 5328b may electrically couple trench structures 5328a of different interconnect layers 5306-5310 together.

The interconnect layers 5306-5310 may include a dielectric material 5326 disposed between the interconnect structures 5328, as shown in FIG. 6. The dielectric material 5326 may include any suitable interlayer dielectric (ILD), such as an oxide (e.g., silicon oxide or aluminum oxide), a nitride (e.g., silicon nitride), a carbide (e.g., silicon carbide), a carbonitride (e.g., silicon carbon nitride), an oxynitride (e.g., silicon oxynitride), or any combination thereof. In some embodiments, the dielectric material 5326 disposed between the interconnect structures 5328 in different ones of the interconnect layers 5306-5310 may have different compositions; in other embodiments, the composition of the dielectric material 5326 between different interconnect layers 5306-5310 may be the same.

A first interconnect layer 5306 (referred to as Metal 1 or “M1”) may be formed directly on the device layer 5304. In some embodiments, the first interconnect layer 5306 may include trench structures 5328a and/or via structures 5328b, as shown. The trench structures 5328a of the first interconnect layer 5306 may be coupled with contacts (e.g., the S/D contacts 5324) of the device layer 5304.

A second interconnect layer 5308 (referred to as Metal 2 or “M2”) may be formed directly on the first interconnect layer 5306. In some embodiments, the second interconnect layer 5308 may include via structures 5328b to couple the trench structures 5328a of the second interconnect layer 5308 with the trench structures 5328a of the first interconnect layer 5306. Although the trench structures 5328a and the via structures 5328b are structurally delineated with a line within each interconnect layer (e.g., within the second interconnect layer 5308) for the sake of clarity, the trench structures 5328a and the via structures 5328b may be structurally and/or materially contiguous (e.g., simultaneously filled during a dual-damascene process) in some embodiments.

A third interconnect layer 5310 (referred to as Metal 3 or “M3”) (and additional interconnect layers, as desired) may be formed in succession on the second interconnect layer 5308 according to similar techniques and configurations described in connection with the second interconnect layer 5308 or the first interconnect layer 5306.

The IC device 5300 may include a solder resist material 5334 (e.g., polyimide or similar material) and one or more bond pads 5336 formed on the interconnect layers 5306-5310. The bond pads 5336 may provide the contacts to couple to the first level interconnects 108, for example. The bond pads 5336 may be electrically coupled with the interconnect structures 5328 and configured to route the electrical signals of the transistor(s) 5340 to other external devices. For example, solder bonds may be formed on the one or more bond pads 5336 to mechanically and/or electrically couple a chip including the IC device 5300 with another component (e.g., a circuit board). The IC device 5300 may have other alternative configurations to route the electrical signals from the interconnect layers 5306-5310 than depicted in other embodiments. For example, the bond pads 5336 may be replaced by or may further include other analogous features (e.g., posts) that route the electrical signals to external components.

FIG. 7 is a cross-sectional side view of an IC device assembly 5400 that may include any of the IC packages 100 disclosed herein. The IC device assembly 5400 includes a number of components disposed on a circuit board 5402 (which may be, e.g., the circuit board 104). The IC device assembly 5400 may include components disposed on a first face 5440 of the circuit board 5402 and an opposing second face 5442 of the circuit board 5402; generally, components may be disposed on one or both faces 5440 and 5442.

In some embodiments, the circuit board 5402 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 5402. In other embodiments, the circuit board 5402 may be a non-PCB substrate.

The IC device assembly 5400 illustrated in FIG. 7 includes a package-on-interposer structure 5436 coupled to the first face 5440 of the circuit board 5402 by coupling components 5416. The coupling components 5416 may electrically and mechanically couple the package-on-interposer structure 5436 to the circuit board 5402, and may include solder balls (as shown in FIG. 7), male and female portions of a socket, an adhesive, an underfill material, and/or any other suitable electrical and/or mechanical coupling structure.

The package-on-interposer structure 5436 may include an IC package 5420 coupled to an interposer 5404 by coupling components 5418. The coupling components 5418 may take any suitable form for the application, such as the forms discussed above with reference to the coupling components 5416. For example, the coupling components 5418 may be the second level interconnects 114. Although a single IC package 5420 is shown in FIG. 7, multiple IC packages may be coupled to the interposer 5404; indeed, additional interposers may be coupled to the interposer 5404. The interposer 5404 may provide an intervening substrate used to bridge the circuit board 5402 and the IC package 5420. The IC package 5420 may be or include, for example, a die (the die 5202 of FIG. 5B), an IC device (e.g., the IC device 5300 of FIG. 6), or any other suitable component. In particular, the IC package 5420 may take the form of any of the embodiments of the IC packages 100 disclosed herein. Generally, the interposer 5404 may spread a connection to a wider pitch or reroute a connection to a different connection. For example, the interposer 5404 may couple the IC package 5420 (e.g., a die) to a ball grid array (BGA) of the coupling components 5416 for coupling to the circuit board 5402. In the embodiment illustrated in FIG. 7, the IC package 5420 and the circuit board 5402 are attached to opposing sides of the interposer 5404; in other embodiments, the IC package 5420 and the circuit board 5402 may be attached to a same side of the interposer 5404. In some embodiments, three or more components may be interconnected by way of the interposer 5404.

The interposer 5404 may be formed of an epoxy resin, a fiberglass-reinforced epoxy resin, a ceramic material, or a polymer material such as polyimide. In some embodiments, the interposer 5404 may be formed of alternate rigid or flexible materials that may include the same materials described above for use in a semiconductor substrate, such as silicon, germanium, and other group III-V and group IV materials. The interposer 5404 may include metal interconnects 5408 and vias 5410, including but not limited to through-silicon vias (TSVs) 5406. The interposer 5404 may further include embedded devices 5414, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio-frequency (RF) devices, power amplifiers, power management devices, antennas, arrays, sensors, and microelectromechanical systems (MEMS) devices may also be formed on the interposer 5404. The package-on-interposer structure 5436 may take the form of any of the package-on-interposer structures known in the art.

The IC device assembly 5400 may include an IC package 5424 coupled to the first face 5440 of the circuit board 5402 by coupling components 5422. The coupling components 5422 may take the form of any of the embodiments discussed above with reference to the coupling components 5416, and the IC package 5424 may take the form of any of the embodiments discussed above with reference to the IC package 5420. In particular, the IC package 5424 may take the form of any of the embodiments of the IC packages 100 disclosed herein.

The IC device assembly 5400 illustrated in FIG. 7 includes a package-on-package structure 5434 coupled to the second face 5442 of the circuit board 5402 by coupling components 5428. The package-on-package structure 5434 may include an IC package 5426 and an IC package 5432 coupled together by coupling components 5430 such that the IC package 5426 is disposed between the circuit board 5402 and the IC package 5432. The coupling components 5428 and 5430 may take the form of any of the embodiments of the coupling components 5416 discussed above, and the IC packages 5426 and 5432 may take the form of any of the embodiments of the IC package 5420 discussed above. In particular, the IC packages 5426 and 5432 may take the form of any of the embodiments of the IC packages 100 disclosed herein, and may include a package substrate 110 with one or more integral devices 112.

FIG. 8 is a block diagram of an example computing device 5500 that may include one or more of the package substrates 110 disclosed herein. For example, any suitable ones of the components of the computing device 5500 may include, or be included in, an IC package 100, in accordance with any of the embodiments disclosed herein. A number of components are illustrated in FIG. 8 as included in the computing device 5500, but any one or more of these components may be omitted or duplicated, as suitable for the application. In some embodiments, some or all of the components included in the computing device 5500 may be attached to one or more motherboards. In some embodiments, some or all of these components are fabricated onto a single system-on-a-chip (SoC) die.

Additionally, in various embodiments, the computing device 5500 may not include one or more of the components illustrated in FIG. 8, but the computing device 5500 may include interface circuitry for coupling to the one or more components. For example, the computing device 5500 may not include a display device 5506, but may include display device interface circuitry (e.g., a connector and driver circuitry) to which a display device 5506 may be coupled. In another set of examples, the computing device 5500 may not include an audio input device 5524 or an audio output device 5508, but may include audio input or output device interface circuitry (e.g., connectors and supporting circuitry) to which an audio input device 5524 or audio output device 5508 may be coupled.

The computing device 5500 may include a processing device 5502 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 5502 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The computing device 5500 may include a memory 5504, which may itself include one or more memory devices such as volatile memory (e.g., dynamic random access memory (DRAM)), nonvolatile memory (e.g., read-only memory (ROM)), flash memory, solid state memory, and/or a hard drive. In some embodiments, the memory 5504 may include memory that shares a die with the processing device 5502. This memory may be used as cache memory and may include embedded dynamic random access memory (eDRAM) or spin transfer torque magnetic random-access memory (STT-MRAM). In some embodiments, the processing device 5502 and/or the memory 5504 may be included in an IC package 100 (e.g., the same IC package 100 or different IC packages 100).

In some embodiments, the computing device 5500 may include a communication chip 5512 (e.g., one or more communication chips). For example, the communication chip 5512 may be configured for managing wireless communications for the transfer of data to and from the computing device 5500. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not. In some embodiments, the communication chip 5512 may be included in an IC package 100.

The communication chip 5512 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra-mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 5512 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 5512 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 5512 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 5512 may operate in accordance with other wireless protocols in other embodiments. The computing device 5500 may include an antenna 5522 to facilitate wireless communications and/or to receive other wireless communications (such as AM or FM radio transmissions).

In some embodiments, the communication chip 5512 may manage wired communications, such as electrical, optical, or any other suitable communication protocols (e.g., the Ethernet). As noted above, the communication chip 5512 may include multiple communication chips. For instance, a first communication chip 5512 may be dedicated to shorter-range wireless communications such as Wi-Fi or Bluetooth, and a second communication chip 5512 may be dedicated to longer-range wireless communications such as GPS, EDGE, GPRS, CDMA, WiMAX, LTE, EV-DO, or others. In some embodiments, a first communication chip 5512 may be dedicated to wireless communications, and a second communication chip 5512 may be dedicated to wired communications.

The computing device 5500 may include battery/power circuitry 5514. The battery/power circuitry 5514 may include one or more energy storage devices (e.g., batteries or capacitors) and/or circuitry for coupling components of the computing device 5500 to an energy source separate from the computing device 5500 (e.g., AC line power).

The computing device 5500 may include a display device 5506 (or corresponding interface circuitry, as discussed above). The display device 5506 may include any visual indicators, such as a heads-up display, a computer monitor, a projector, a touchscreen display, a liquid crystal display (LCD), a light-emitting diode display, or a flat panel display, for example.

The computing device 5500 may include an audio output device 5508 (or corresponding interface circuitry, as discussed above). The audio output device 5508 may include any device that generates an audible indicator, such as speakers, headsets, or earbuds, for example.

The computing device 5500 may include an audio input device 5524 (or corresponding interface circuitry, as discussed above). The audio input device 5524 may include any device that generates a signal representative of a sound, such as microphones, microphone arrays, or digital instruments (e.g., instruments having a musical instrument digital interface (MIDI) output).

The computing device 5500 may include a global positioning system (GPS) device 5518 (or corresponding interface circuitry, as discussed above). The GPS device 5518 may be in communication with a satellite-based system and may receive a location of the computing device 5500, as known in the art.

The computing device 5500 may include an other output device 5510 (or corresponding interface circuitry, as discussed above). Examples of the other output device 5510 may include an audio codec, a video codec, a printer, a wired or wireless transmitter for providing information to other devices, or an additional storage device.

The computing device 5500 may include an other input device 5520 (or corresponding interface circuitry, as discussed above). Examples of the other input device 5520 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 5500 may have any desired form factor, such as a hand-held or mobile computing device (e.g., a cell phone, a smart phone, a mobile internet device, a music player, a tablet computer, a laptop computer, a netbook computer, an ultrabook computer, a personal digital assistant (PDA), an ultra-mobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 5500 may be any other electronic device that processes data.

The following paragraphs provide various examples of the embodiments disclosed herein.

Example 1 is an integrated circuit (IC) package, including: a package substrate; a plurality of electrical components secured to a face of the package substrate; and a plate secured to the plurality of electrical components with an adhesive such that the plurality of electrical components are between the plate and the package substrate.

Example 2 may include the subject matter of Example 1, and may further specify that a thickness of the plate is less than 100 microns.

Example 3 may include the subject matter of any of Examples 1-2, and may further specify that a thickness of the plate is less than 50 microns.

Example 4 may include the subject matter of any of Examples 1-3, and may further specify that the adhesive does not contact the package substrate.

Example 5 may include the subject matter of any of Examples 1-4, and may further specify that the plurality of electrical components are secured to the face of the substrate with first level interconnects.

Example 6 may include the subject matter of any of Examples 1-5, and may further specify that the face is a first face, the package substrate has a second face opposite to the first face, and the IC package further includes second level interconnects at the second face of the package substrate.

Example 7 may include the subject matter of Example 6, and may further include at least one electrical component secured to the second face of the package substrate with first level interconnects.

Example 8 may include the subject matter of Example 7, and may further specify that the at least one electrical component secured to the second face of the package substrate includes a processing die.

Example 9 may include the subject matter of Example 8, and may further specify that the processing die is a central processing unit (CPU) die.

Example 10 may include the subject matter of any of Examples 7-8, and may further specify that an underfill material is between the at least one electrical component and the second face of the package substrate.

Example 11 may include the subject matter of Example 10, and may further specify that no underfill material is between the plurality of electrical components and the first face of the package substrate.

Example 12 may include the subject matter of any of Examples 1-11, and may further specify that the plate includes at least one recessed portion in a face facing the plurality of electrical components.

Example 13 may include the subject matter of Example 12, and may further specify that the surface of the plate is a first face, the plate has a second face opposite to the first face, and the second face is flat.

Example 14 may include the subject matter of any of Examples 1-13, and may further specify that the plurality of electrical components have heights above the package substrate that are less than 1 millimeter.

Example 15 may include the subject matter of any of Examples 1, and may further specify that at least one of the electrical components has a height above the package substrate less than 500 microns.

Example 16 may include the subject matter of any of Examples 1-15, and may further specify that no thermal interface material is between the plate and the package substrate.

Example 17 may include the subject matter of any of Examples 1-16, and may further specify that the plate has a thermal conductivity less than 385 watts per meter kelvin.

Example 18 may include the subject matter of any of Examples 1-17, and may further specify that the plate has a thermal conductivity less than 205 watts per meter kelvin.

Example 19 may include the subject matter of any of Examples 1-18, and may further specify that the plate includes a plastic material.

Example 20 may include the subject matter of any of Examples 1-19, and may further specify that the plate includes a ceramic material.

Example 21 may include the subject matter of any of Examples 1-20, and may further specify that the plate includes a metal material.

Example 22 may include the subject matter of any of Examples 1-21, and may further specify that no underfill material is between the plurality of electrical components and the package substrate.

Example 23 may include the subject matter of any of Examples 1-22, and may further specify that no mold material surrounds the plurality of electrical components.

Example 24 is a computing device, including: a circuit board; and an integrated circuit (IC) package disposed on the circuit board, wherein the IC package includes a package substrate, a plurality of electrical components secured to a face of the package substrate, and a plate secured to the plurality of electrical components such that the plurality of electrical components are between the plate and the package substrate.

Example 25 may include the subject matter of Example 24, and may further specify that the plate includes a metal, plastic, or ceramic material.

Example 26 may include the subject matter of any of Examples 24-25, and may further specify that the IC package has a footprint area less than or equal to 2 square centimeters.

Example 27 may include the subject matter of any of Examples 24-26, and may further specify that the face is a first face, the package substrate has a second face opposite to the first face, and the IC package further includes an electrical component secured to the second face.

Example 28 may include the subject matter of any of Examples 24-27, and may further specify that the plurality of electrical components includes at least one radio frequency (RF) component.

Example 29 may include the subject matter of any of Examples 24-28, and may further specify that the IC package is coupled to the circuit board with second level interconnects.

Example 30 may include the subject matter of any of Examples 24-29, and may further specify that at least one of the plurality of electrical components is secured to the face of the package substrate with solder bumps.

Example 31 is a method of manufacturing an integrated circuit (IC) package, including: coupling first and second electrical components to a face of a package substrate; providing an adhesive on a top surface of the first electrical component and on a top surface of the second electrical component; and bringing a plate in contact with the adhesive.

Example 32 may include the subject matter of Example 31, and may further specify that the adhesive is a flip chip underfill material.

Example 33 may include the subject matter of any of Examples 31-32, and may further specify that the first and second electrical components have different heights, and providing the adhesive on the top surface of the first electrical component and on the top surface of the second electrical component includes providing a different amount of adhesive on the top surface of the first electrical component and on the top surface of the second electrical component.

Example 34 may include the subject matter of any of Examples 31-33, and may further specify that the face is a first face, the package substrate has a second face opposite to the first face, and the method further includes coupling a third electrical component to the second face of the package substrate.

Example 35 may include the subject matter of any of Examples 31-34, and may further specify that the face is a first face, the package substrate has a second face opposite to the first face, and the method further includes forming second level interconnects on the second face of the package substrate.

1. An integrated circuit (IC) package, comprising:
a package substrate;
a plurality of electrical components secured to a face of the package substrate; and
a plate secured to the plurality of electrical components with an adhesive such that the plurality of electrical components are between the plate and the package substrate.

2. The IC package of claim 1, wherein a thickness of the plate is less than 100 microns.

3. (canceled)

4. The IC package of claim 1, wherein the adhesive does not contact the package substrate.

5. The IC package of claim 1, wherein the face is a first face, the package substrate has a second face opposite to the first face, and the IC package further includes:
second level interconnects at the second face of the package substrate.

6. The IC package of claim 5, further comprising:
at least one electrical component secured to the second face of the package substrate with first level interconnects.

7. The IC package of claim 6, wherein the at least one electrical component secured to the second face of the package substrate includes a processing die.

8. The IC package of claim 6, wherein an underfill material is between the at least one electrical component and the second face of the package substrate.

9. The IC package of claim 8, wherein no underfill material is between the plurality of electrical components and the first face of the package substrate.

10. The IC package of claim 1, wherein the plate includes at least one recessed portion in a face facing the plurality of electrical components.

11. The IC package of claim 10, wherein the face of the plate is a first face, the plate has a second face opposite to the first face, and the second face is flat.

12-13. (canceled)

14. The IC package of claim 1, wherein no thermal interface material is between the plate and the package substrate.

15. The IC package of claim 1, wherein the plate has a thermal conductivity less than 205 watts per meter kelvin.

16. The IC package of claim 1, wherein no underfill material is between the plurality of electrical components and the package substrate.

17. The IC package of claim 1, wherein no mold material surrounds the plurality of electrical components.

18. A computing device, comprising:
a circuit board; and
an integrated circuit (IC) package disposed on the circuit board, wherein the IC package includes:
a package substrate,
a plurality of electrical components secured to a face of the package substrate, and
a plate secured to the plurality of electrical components such that the plurality of electrical components are between the plate and the package substrate.

19. The computing device of claim 18, wherein the plate includes a metal, plastic, or ceramic material.

20. (canceled)

21. The computing device of claim 18, wherein at least one of the plurality of electrical components is secured to the face of the package substrate with solder bumps.

22. A method of manufacturing an integrated circuit (IC) package, comprising:
coupling first and second electrical components to a face of a package substrate;
providing an adhesive on a top surface of the first electrical component and on a top surface of the second electrical component; and
bringing a plate in contact with the adhesive.

23. The method of claim 22, wherein the adhesive is a flip chip underfill material.

24. The method of claim 22, wherein the first and second electrical components have different heights, and providing the adhesive on the top surface of the first electrical component and on the top surface of the second electrical component includes providing a different amount of adhesive on the top surface of the first electrical component and on the top surface of the second electrical component.

25. (canceled)
